(19) United States
(12) Patent Application Publication
(10) Pub. No.: US 2026/0123463 A1
(43) Pub. Date: Apr. 30, 2026

(54) PROCESS FOR MANUFACTURING OF A HETEROGENEOUS INTEGRATED SYSTEM

(71) Applicant: STMicroelectronics International N.V., Geneva (CH)

(72) Inventors: Paolo COLPANI, Agrate Brianza (IT); Michele MOLGG, Agrate Brianza (MB) (IT)

(73) Assignee: STMicroelectronics International N.V., Geneva (CH)

(21) Appl. No.: 19/364,630

(22) Filed: Oct. 21, 2025

(30) Foreign Application Priority Data
Oct. 24, 2024 (IT) 102024000023712

(51) Int. Cl. H01L 23/00

(52) U.S. Cl. CPC H10W 70/60; H10W 70/09

(57) ABSTRACT

A heterogeneous integrated system includes first and second chiplets and a complete electrical connection stack with a total number of levels of metallization layers. The first and second chiplets include respective first and second wafers based on different semiconductor materials. Each chiplet includes a substrate having a back surface and a front surface where functional circuits are formed. The back surfaces of the chiplets are bonded to a carrier substrate made of semiconductor material. A common portion of the complete stack is formed above the front surfaces of the chiplets, that common portion including a given number of levels of metallization layers shared in common between the chiplets. The given number is greater than or equal to one and lower than or equal to the total number of levels of metallization layers.

### PRIORITY CLAIM

This application claims the priority benefit of Italian Application for Patent No. 102024000023712 filed on Oct. 24, 2024, the content of which is hereby incorporated by reference in its entirety to the maximum extent allowable by law.

### TECHNICAL FIELD

The present solution relates to a process for manufacturing of a heterogeneous integrated system and to a corresponding heterogeneous integrated system.

### BACKGROUND

As is known, in the semiconductor industry there is frequently a need to provide heterogeneous integrated systems (or chips), that is, systems made with different technologies and/or different materials, such as silicon, silicon on insulator (SOI), gallium nitride (GaN), silicon carbide (SiC), or others.

Important advantages may in fact be obtained in terms of performance and area occupation by integrating multiple devices, heterogeneous with each other, within a single package, providing a so-called System-In-Package (SIP).

For example, a wide bandgap semiconductor device, such as a GaN or SiC device, may advantageously be integrated with a silicon device, BCD or CMOS, in order to exploit the best features of both technologies and/or both materials in a single integrated system.

So-called 2.5D or 3D integration solutions are known, for example in the field of memories and advanced computing, which in general envisage stacking within a same package two or more “chiplets” (i.e., complete integrated devices, each provided in a respective die, but without a protective package, each having its own function and being optimized from the point of view of the corresponding manufacturing techniques and/or technological nodes).

Examples of 3D integration of chiplets are described for example in United States Patent Application Publication No. 2023/0041839A1 or PCT Application WO 2022/252087A1 (both of which are incorporated herein by reference).

These 2.5 or 3D integration techniques, although advantageous in some application fields, are in general of complex implementation, requiring high costs and elaborate manufacturing techniques, in particular with respect to dedicated final assembly steps of the various chiplets (so-called back-end or Back-End-Of-the-Line, BEOL, steps).

There is accordingly a need to the art to overcome the limitations of known processes and systems and to provide an answer to the aforementioned need for integration of heterogeneous semiconductor devices.

### SUMMARY

According to the present solution, a process for manufacturing a heterogeneous integrated system and a corresponding integrated system are provided.

In an embodiment, a process for manufacturing a heterogeneous integrated system (comprising a first and a second finished chiplets, said first and second finished chiplets having a complete electrical connection stack with a total number of levels of metallization layers) comprises: forming a first and a second semi-finished chiplets starting from a respective first and second wafer based on different semiconductor materials, said first and second semi-finished chiplets including a respective substrate having a respective back surface and a respective front surface, opposite to the respective back surface, where respective functional components or elements are at least in part formed; coupling adjacent to each other said first and second semi-finished chiplets on a common temporary support wafer having a coupling surface, with said front surface arranged facing said coupling surface and with said back surface free; bonding in a permanent manner a carrier substrate of semiconductor material at said back surface of said respective substrates; decoupling and removing said temporary support wafer from said first and second semi-finished chiplets; and subsequently, forming above said front surface of the respective substrates a common portion of said complete stack comprising a given number of levels of metallization layers in common between said first and second semi-finished chiplets to form said first and second finished chiplets, wherein said given number is greater than or equal to one and lower than or equal to said total number of levels of metallization layers.

In an embodiment, a heterogeneous integrated system comprises: a carrier substrate; a first and a second finished chiplets including a respective substrate, respectively of a first and a second semiconductor material different from each other, and having a respective back surface and a respective front surface, opposite to the respective back surface, where respective functional components or elements are at least in part formed, said first and second finished chiplets being arranged adjacent to each other, coupled above a coupling surface of said carrier substrate at the back surface of the respective substrates; wherein said first and second finished chiplets comprise a complete electrical connection stack with a total number of levels of metallization layers and formed above the front surface of the respective substrates; wherein said complete stack comprises a common portion with a given number of metallization layers in common between said first and second finished chiplets, said given number being greater than or equal to one and lower than or equal to said total number of levels of metallization layers.

### BRIEF DESCRIPTION OF THE DRAWINGS

For a better understanding of the present invention, a preferred embodiment thereof is now described, purely by way of non-limiting example and with reference to the attached drawings, wherein:

FIGS. 1A and 1B show schematic cross-sections of a first, respectively, second semi-finished chiplet, heterogeneous with each other;

FIGS. 2-8 show schematic cross-sections of a heterogeneous integrated system, in successive steps of a corresponding manufacturing process; and

FIG. 9 shows a schematic cross-section of a variant embodiment of the heterogeneous integrated system.

### DETAILED DESCRIPTION

As will be described in detail below, one aspect of the present solution envisages the provision, with so-called front-end manufacturing techniques, of semi-processed (or semi-finished) chiplets, each using a respective technology and a respective substrate of semiconductor material. In particular, such semi-finished chiplets have a complete front-end (or Front-End-Of-the-Line (FEOL)) processing, as to the functional components or elements within the respective substrate, but are not complete as to metal interconnection layers or levels above the same substrate (such layers being designed to provide, in a known manner, the electrical connection of the respective functional components or elements towards an external environment, for example towards a different device or integrated system).

For example, semi-finished chiplets do not have any metal interconnection layer or level above the respective substrate, or at most have one or two of such metal interconnection levels (i.e., the levels most proximal to the respective semiconductor substrate), for example comprising a pre-metallization level, so-called Pre-Metal Dielectric (PMD) level.

The semi-finished chiplets are subsequently arranged on a common substrate and the corresponding manufacturing is completed with common final processing steps, in particular for forming (or completing) the aforementioned metal interconnection layers or levels, thereby obtaining a resulting heterogeneous, monolithic, integrated system (or chip), ready for back-end (or Back-End-Of-the-Line (BEOL)) processing steps, for example for assembly in a corresponding package (which defines the mechanical and electrical interface towards an external environment).

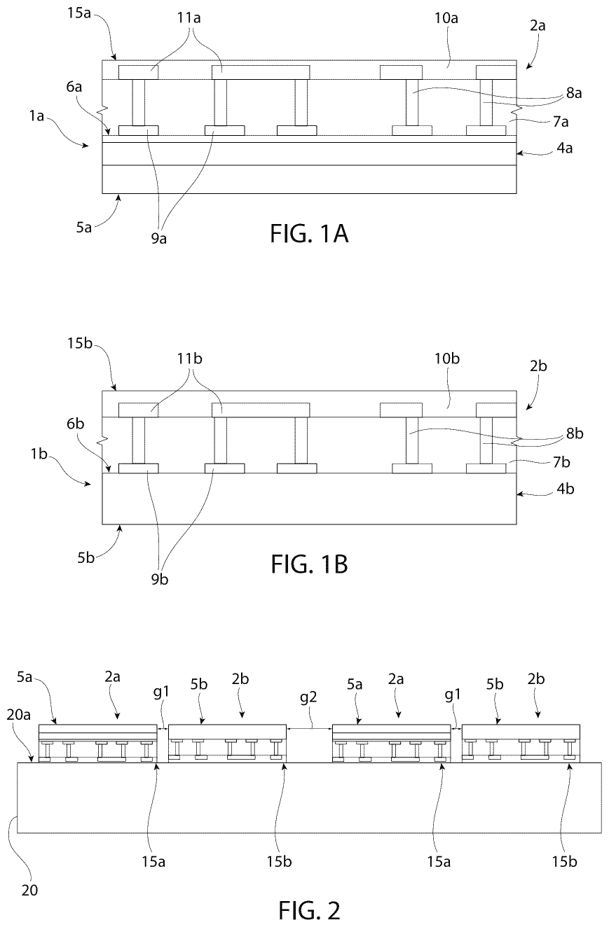

With reference to FIGS. 1A and 1B, a first and a second semi-finished chiplets, indicated by 2a and 2b, are shown, by way of example, having been previously formed with front-end manufacturing steps (FEOL—known and not illustrated and not described in detail) starting from respective wafers, advantageously made of semiconductor materials different from each other (for example silicon and silicon carbide or gallium nitride) and/or with technologies different from each other (for example using different technological nodes).

For example, the first chiplet 2a may be obtained starting from a first wafer 1a comprising BCD (Bipolar-CMOS-DMOS) type silicon; and the second chiplet 2b may be obtained starting from a second wafer 1b comprising gallium nitride (GaN), containing discrete or monolithic power components.

The first and the second semi-finished chiplets 2a, 2b have a respective substrate 4a, 4b wherein respective functional elements or components, not illustrated here, have been formed in a known manner (with respective initial, front-end processing steps), for example control transistors in the case of the first semi-finished chiplet 2a or power transistors in the case of the second semi-finished chiplet 2b.

The aforementioned substrates 4a, 4b have a respective back surface 5a, 5b and a respective front surface 6a, 6b.

Above the front surface 6a, 6b the semi-finished chiplets 2a, 2b have, in the illustrated embodiment, a respective upper layer 7a, 7b, for example made of dielectric material, such as silicon oxide; and through vias 8a, 8b, filled with conductive material (for example made of tungsten), traverse an entire thickness of the respective upper layer 7a, 7b.

In detail, these through vias 8a, 8b each have a first end coupled to respective electrical contact elements 9a, 9b (for example pads, connection tracks or the like) formed on the front surface 6a, 6b of the respective substrate 4a, 4b (for example electrically connected to source or drain regions of the aforementioned transistors) and a second end at the level of an external surface of the respective upper layer 7a, 7b (arranged at a distance from the respective substrate 4a, 4b).

The aforementioned functional elements or components may be alternatively, or additionally, formed within the aforementioned respective upper layer 7a, 7b, for example laterally to the through vias 8a, 8b (which in this case define, together with the aforementioned respective electrical contact elements 9a, 9b, a first local interconnection level).

In the illustrated embodiment, the first and the second semi-finished chiplets 2a, 2b also include a pre-metallization dielectric (PMD) layer 10a, 10b, arranged on the external surface of the respective upper layer 7a, 7b, having a separation function with respect to an overlying stack of interconnection metallization layers (which will be subsequently formed in final processing steps). Within this pre-metallization dielectric layer 10a, 10b further electrical contact elements 11a, 11b (for example contact pads or electrical tracks or paths) are formed, electrically connected to the aforementioned second ends of the through vias 8a, 8b.

However, it is highlighted that the semi-finished chiplets 2a, 2b may possibly not include this pre-metallization dielectric layer 10a, 10b; or, alternatively, may also include one or more metallization levels above the same pre-metallization dielectric layer 10a, 10b (in any case, these one or more metallization levels of the semi-finished chiplet are fewer in number than those that the finished chiplet will have, as described below).

In particular, in a possible embodiment, the aforementioned initial processing steps may envisage the formation of a first number Mₐ of metallization levels for the first semi-finished chiplet 2a and a second number M_{b} (which may differ from the first number Mₐ) of metallization levels for the second semi-finished chiplet 2b.

The semi-finished chiplets 2a, 2b in any case have, at the end of the corresponding initial front-end manufacturing steps, a front external surface, indicated by 15a, 15b in the aforementioned FIGS. 1A and 1B, opposite to the back surfaces 5a, 5b of the corresponding substrates 4a, 4b, which may be defined, depending on the cases, by the last dielectric layer or by the last metallization level possibly present (in the example depicted in FIGS. 1A and 1B, such front external surfaces 15a, 15b are defined by the respective pre-metallization dielectric layers 10a, 10b).

It is again highlighted that the semi-finished chiplets 2a, 2b do not have a complete processing, in particular they do not include a stack of electrical connection metallization layers (or, as already indicated, they include an incomplete stack).

The manufacturing process may then envisage, in a possible implementation example, performing a step of removal of material from the back (so-called “backgrinding” step) starting from the back surfaces 5a, 5b of the substrates 4a, 4b of the semi-finished chiplets 2a, 2b, followed by a step of cleaning and finishing of the back surfaces, again indicated by 5a, 5b, resulting from this removal step.

Possibly, the removal of material may have the target of achieving a same final thickness or in any case a desired thickness value for the semi-finished chiplets 2a, 2b (this thickness being considered along a direction orthogonal to the aforementioned back surfaces 5a, 5b or front surfaces 6a, 6b of the respective substrates 4a, 4b).

As shown in FIG. 2, the manufacturing process continues with the positioning (with so-called “pick & place” technique) above a common temporary support wafer 20 of the first and second semi-finished chiplets 2a, 2b (which have been subject to separate and distinct processing up to this point), in particular of corresponding dies obtained from the corresponding first and second wafers 1a, 1b by means of a dicing step.

As shown in the aforementioned FIG. 2, the semi-finished chiplets 2a, 2b are coupled (for example by means of oxide/oxide coupling) with the aforementioned external surface 15a, 15b in contact with a coupling surface 20a of the temporary support wafer 20 and with the back surfaces 5a, 5b of the corresponding substrates 4a, 4b arranged at a distance from the same coupling surface 20a and available for subsequent processing.

In particular, the semi-finished chiplets 2a, 2b are coupled adjacent to each other above the temporary support wafer 20 with a first separation gap g1 therebetween.

As shown in the same FIG. 2, in this step a plurality of pairs formed by a respective first semi-finished chiplet 2a and a respective second semi-finished chiplet 2b may advantageously be coupled on the temporary support wafer 20 (each pair being intended, as will be described below, for providing a respective heterogeneous integrated system or chip). The pairs are also coupled adjacent to each other above the temporary support wafer 20 with a second separation gap g2 therebetween, which is in the example larger than the first separation gap g1.

In particular, each semi-finished chiplet 2a, 2b is positioned in direct contact with the temporary support wafer 20 (in other words, a single layer of semi-finished chiplets is formed, without any semi-finished chiplet overlapping another semi-finished chiplet).

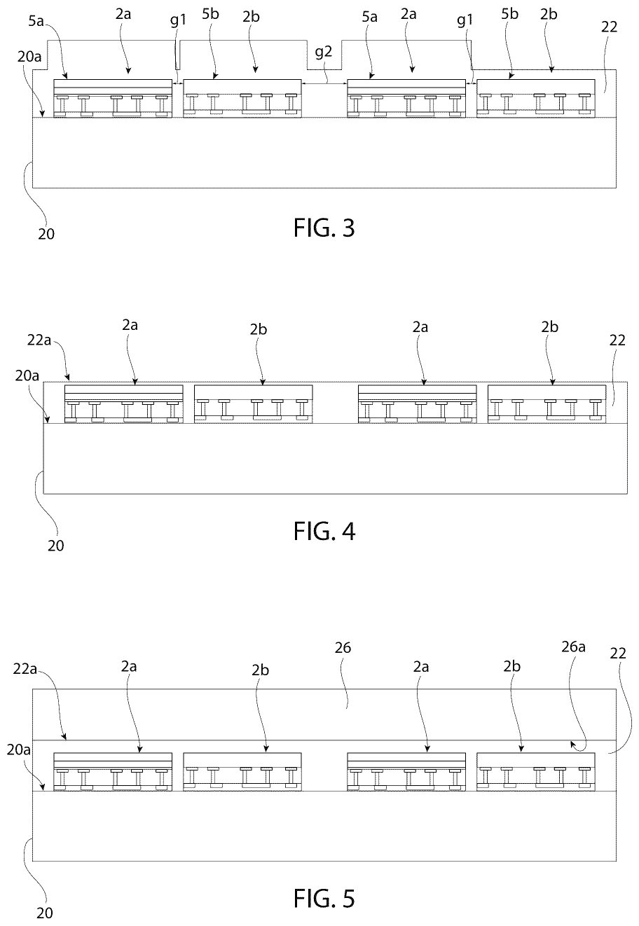

Afterwards, as shown in FIG. 3, a deposition step may be performed above the coupling surface 20a of the temporary support wafer 20 of a thick dielectric layer 22, for example of silicon oxide or Tetra-Ethyl Ortho-Silicate (TEOS).

This thick dielectric layer 22, having a greater thickness than the thickness of the semi-finished chiplets 2a, 2b, covers the back surfaces 5a, 5b of the respective substrates 4a, 4b of the first and the second semi-finished chiplets 2a, 2b and also fills the aforementioned first and second separation gaps g1, g2 between the same semi-finished chiplets 2a, 2b of each pair and between the pairs of semi-finished chiplets 2a, 2b.

As shown in FIG. 4, a planarization step may then be performed (for example with Chemical Mechanical Polishing (CMP) technique) of the aforementioned thick dielectric layer 22, which therefore assumes a substantially planar front surface 22a (arranged at a distance from the aforementioned coupling surface 20a of the temporary support wafer 20).

The manufacturing process proceeds, FIG. 5, with a permanent bonding step of a carrier substrate 26, in particular made of semiconductor material, for example silicon, to the aforementioned front surface 22a that has been previously planarized; such bonding may for example be of the oxide/oxide type (an oxide layer being in this case envisaged on a coupling surface 26a of the aforementioned carrier substrate 26, designed for contact with the aforementioned front surface 22a).

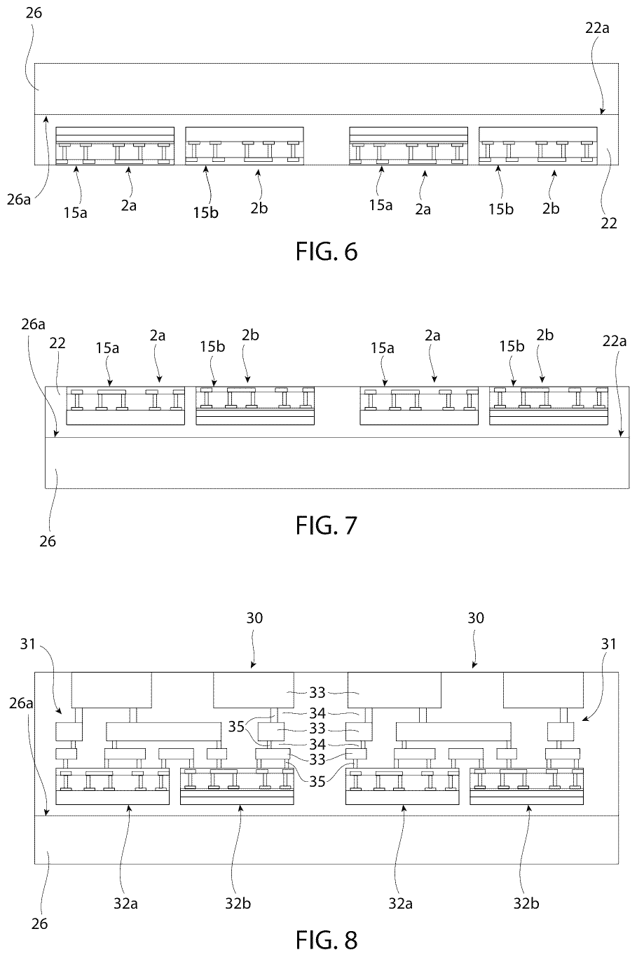

Then, as shown in FIG. 6, the temporary support wafer 20 is decoupled from the semi-finished chiplets 2a, 2b and removed.

Afterwards, FIG. 7, a flipping step of the carrier substrate 26 and of the coupled semi-finished chiplets 2a, 2b is performed, in such a way that the aforementioned front external surfaces 15a, 15b of the same semi-finished chiplets 2a, 2b is available for subsequent processing, which in particular envisage final processing steps (so-called back-end steps corresponding to BEOL processing) of the semi-finished chiplets 2a, 2b for completing the corresponding electrical connection stacks.

As previously indicated, such final processing steps are therefore implemented in common for the first and the second semi-finished chiplets 2a, 2b.

As illustrated in FIG. 8, the aforementioned final processing steps thus complete the processing of the semi-finished chiplets 2a, 2b, thereby leading to the complete formation of a respective integrated system, denoted with 30, wherein a common complete stack 31 for electrical connection is formed above the substrates 4a, 4b, defining the metallization levels of the finished chiplets, here denoted with 32a, 32b, and also the electrical interconnections between the same finished chiplets 32a, 32b.

Such complete stack 31 is formed, in a known manner, by a certain number of levels of metallization layers 33, of interdielectric layers 34 interposed between the same metallization layers 33 and of connection vias 35 arranged vertically through the interdielectric layers 34 for the electrical connection between adjacent levels of metallization layers 33.

In this case, the interdielectric layers 34 extend in a continuous manner above both finished chiplets 32a, 32b; and one or more of the metallization layers 33 extend partly above a first finished chiplet 32a and partly above a second finished chiplet 32b, forming the respective electrical interconnection.

The aforementioned complete stack 31 is monolithic and in common between the finished chiplets 32a, 32b, which therefore do not have respective and distinct stacks of electrical connection, thus avoiding the need to envisage separate electrical interconnections between separate stacks (as typically envisaged in known solutions).

In greater detail, if the total number of metallization levels of the complete stack 31 is defined with N, the aforementioned final processing steps therefore envisage the formation of a number Zₐ and Z_{b} of metallization levels for the first and, respectively, the second finished chiplets 32a, 32b, where: Zₐ=N−Mₐ and Z_{b}=N−M_{b}.

Purely by way of example, the aforementioned FIG. 8 shows a total number N of metallization levels equal to three in the aforementioned complete stack 31.

In general, advantageously, the described solution provides complete flexibility as to the metallization levels of the aforementioned semi-finished chiplets 2a, 2b (if any) and of the resulting finished chiplets 32a, 32b. Furthermore, where required, the manufacturing process may envisage one (or multiple) leveling metallization levels to be formed to compensate for any differences between the semi-finished chiplets 2a, 2b having a different number of metallization levels.

The manufacturing process of the integrated system 30 may therefore terminate with dicing steps of the carrier substrate 26, in such a way as to completely define each heterogeneous integrated system (or chip), formed by the respective pair of finished chiplets 32a, 32b, including the corresponding substrates 4a, 4b and the corresponding complete stack 31.

Further processing steps (of a known type, here not illustrated) may then be performed for the assembly of the heterogeneous system within a package.

The advantages of the proposed solution are clear from the preceding description.

In any case, it is again underlined that this solution allows heterogeneous integrated systems to be obtained, with wide flexibility in terms of technologies, starting materials and metallization levels of the corresponding heterogeneous chiplets, with a process that is inexpensive and easy to implement.

In particular, this solution allows to exploit, for manufacturing of the aforementioned integrated systems, consolidated techniques for forming the front-end of the semi-finished chiplets and in particular to exploit common steps to terminate the processing of the same chiplets, as to a corresponding common metallization stack. Furthermore, consolidated back-end techniques may be used for the final assembly in a package, without requiring specific dedicated measures.

Finally, it is clear that modifications and variations may be made to what has been described and illustrated here without thereby departing from the scope of the present invention, as defined in the attached claims.

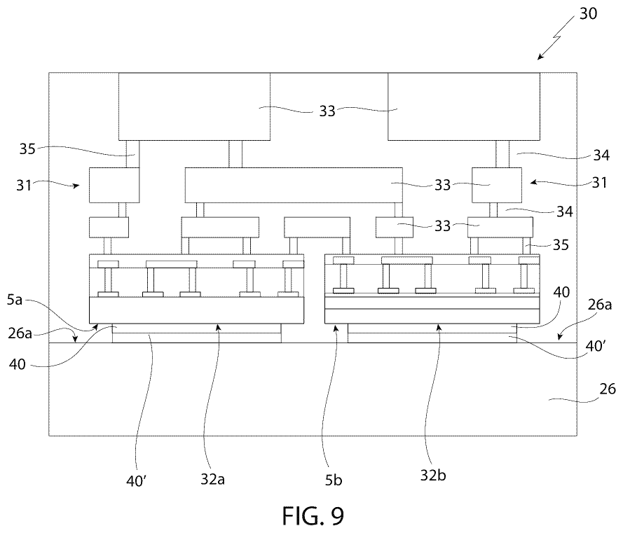

In particular, as shown in FIG. 9, a possible alternative embodiment of the integrated system 30 may envisage, after the planarization step (reference may be made to the aforementioned FIG. 4), a step of formation of a back metallization 40, for example of copper, above the back surfaces 5a, 5b of the substrates 4a, 4b of the semi-finished chiplets 2a, 2b.

Advantageously, this back metallization 40 allows simplifying the subsequent coupling between the semi-finished chiplets 2a, 2b and the carrier substrate 26 (as shown in the aforementioned FIG. 9). In particular, the coupling surface 26a of the aforementioned carrier substrate 26 may in this case have respective metallization regions 40′ at the semi-finished chiplets 2a, 2b, for coupling with the aforementioned back metallizations 40.

Additionally, as shown in FIG. 9, one or more metallization layers 33 may extend above both the first chiplet 32a and the second chiplet 32b, forming part of an electrical interconnection between the chiplets 32a and 32b.

In general, it is again underlined that the described solution may find advantageous application regardless of the manufacturing technologies of the semi-finished chiplets and the types of material of the corresponding substrates.

1. A process for manufacturing a heterogeneous integrated system, comprising:
forming first and second semi-finished chiplets starting from respective first and second wafers based on different semiconductor materials, said first and second semi-finished chiplets including a respective substrate having a respective back surface and a respective front surface, opposite to the respective back surface, where respective functional components or elements are at least in part formed;
mounting said first and second semi-finished chiplets adjacent to each other on a common temporary support wafer having a coupling surface, with said front surfaces arranged facing said coupling surface and with said back surfaces that are free;
bonding in a permanent manner a carrier substrate made of semiconductor material at said back surfaces of said respective substrates that are free;
decoupling and removing said temporary support wafer from said first and second semi-finished chiplets; and
subsequently forming a common portion of a complete electrical connection stack above said front surfaces of the respective substrates, said complete electrical connection stack having a total number of levels of metallization layers, and said common portion comprising a given number of levels of metallization layers in common between said first and second semi-finished chiplets, wherein said given number is greater than or equal to one and lower than or equal to said total number of levels of metallization layers.

2. The process according to claim 1, wherein said complete electrical connection stack further comprises interdielectric layers interposed between said metallization layers and connection vias arranged vertically through respective interdielectric layers for the electrical connection between adjacent levels of said metallization layers.

3. The process according to claim 1, further comprising forming a respective initial number of levels of metallization layers above said front surfaces of the respective substrates, said respective initial number being greater than or equal to one and lower than said total number; and wherein forming said common portion comprises forming a respective remaining number of levels of metallization layers; wherein said total number is given by a sum of said respective initial number and respective remaining number.

4. The process according to claim 1, wherein forming said first and second semi-finished chiplets comprises forming said first and second semi-finished chiplets without levels of metallization layers, and wherein forming said common portion comprises forming said total number of levels of metallization layers.

5. The process according to claim 1, wherein coupling said first and second semi-finished chiplets on said common temporary support wafer comprises positioning said first and second semi-finished chiplets adjacent to each other with a separation gap therebetween; said process further comprising, prior to said step of bonding in a permanent manner said carrier substrate, forming above the coupling surface of the temporary support wafer a dielectric layer to cover the back surfaces of said respective substrates of the first and second semi-finished chiplets and further filling said separation gap.

6. The process according to claim 5, further comprising performing a planarization of said dielectric layer to form a front surface, arranged at a distance from said coupling surface of the temporary support wafer, that is substantially planar.

7. The process according to claim 1, further comprising: forming, above the front surface, a respective dielectric layer and through vias, filled with conductive material, which traverse the entire thickness of the respective dielectric layer, said through vias having a first end coupled to respective electrical contact elements formed on the front surface of the respective substrate and a second end arranged level with an external surface of the respective dielectric layer, arranged at a distance from the respective substrate; and forming a pre-metallization dielectric layer arranged on the external surface of the respective dielectric layer, having a separation function with respect to the complete electrical connection stack.

8. The process according to claim 1, wherein the semiconductor material of said first wafer comprises silicon and the semiconductor material of said second wafer comprises gallium nitride.

9. The process according to claim 1, further comprising, prior to bonding, forming a metallization region on the back surfaces of the respective substrates of said first and second semi-finished chiplets, said metallization region configured to facilitate coupling between said first and second semi-finished chiplets and said carrier substrate; wherein the coupling surface of said carrier substrate has respective metallization regions at said first and second semi-finished chiplets, to provide said coupling with the metallization region formed on the back surfaces of the respective substrates.

10. A heterogeneous integrated system, comprising:
a carrier substrate;
first and second chiplets each including a respective substrate, respectively made of first and second semiconductor materials different from each other, and having respective back surfaces and respective front surfaces, opposite to the respective back surfaces, where respective functional components or elements are at least in part formed, said first and second chiplets being arranged adjacent to each other;
wherein the back surface of the respective substrates are coupled above a coupling surface of said carrier substrate;
a complete electrical connection stack with a total number of levels of metallization layers formed above the front surfaces of the respective substrates;
wherein said complete electrical connection stack comprises a common portion with a given number of metallization layers in common between said first and second chiplets, said given number being greater than or equal to one and lower than or equal to said total number of levels of metallization layers.

11. The system according to claim 10, wherein said complete electrical connection stack further comprises interdielectric layers interposed between said metallization layers and connection vias arranged vertically through respective interdielectric layers for the electrical connection between adjacent levels of said metallization layers.

12. The system according to claim 11, wherein said interdielectric layers extend in a continuous manner above the respective substrates of said first and second finished chiplets and one or more of the metallization layers extend in part above the respective substrate of the first finished chiplet and in part above the respective substrate of the second finished chiplet, providing the respective electrical interconnection.
